(19) United States
(12) Patent Application Publication
(10) Pub. No.: US 2026/0237606 A1
(43) Pub. Date: Aug. 13, 2026

(54) RADIO FREQUENCY (RF) CHOKE FOR PARTICLE REDUCTION AND INCREASED CONDUCTANCE IN PRECLEAN CHAMBER

(71) Applicant: Applied Materials, Inc., Santa Clara, CA (US)

(72) Inventors: Prashant AGARWAL, Singapore (SG); Ananthkrishna JUPUDI, Singapore (SG); Kang ZHANG, Singapore (SG)

(21) Appl. No.: 19/053,351

(22) Filed: Feb. 13, 2025

(51) Int. Cl. H01J 37/32

(52) U.S. Cl. CPC H01J 37/32174; H01J 37/32642; H01J 37/32862

(57) ABSTRACT

Certain aspects provided herein generally include apparatus, plasma processing systems and methods for chamber cleaning. One example apparatus generally includes: a plasma impeding element disposed adjacent to a substrate support element of a chamber, wherein the plasma impeding element includes a surface with one or more openings configured to allow fluid flow from an upper region of the chamber to a lower region of the chamber; and one or more straps coupled configured to be coupled between the plasma impeding element and a grounded body, wherein the one or more straps are disposed within the lower region of the chamber.

### BACKGROUND

### Field

Certain aspects of the present disclosure generally relate to a system and methods used in semiconductor device manufacturing. More specifically, aspects of the present disclosure relate to a radio frequency (RF) choke for a plasma chamber.

### Description of the Related Art

Process chambers configured to perform a preclean process are known. For example, such chambers are configured to remove native oxide on metal contact pads of a substrate prior to physical vapor deposition (PVD) for depositing one or more barrier layers, e.g., titanium (Ti), copper (Cu), etc., on the substrate and to remove other materials. Preclean chambers, typically, use ion bombardment (induced by RF plasma) to remove the native oxide on the metal contact pads and other materials. For example, the preclean process can etch the native oxide and material from the substrate. The preclean process is configured to lower contact resistance between the metal contacts on the substrate to enhance performance and power consumption of integrated circuits on the substrate and to promote adhesion.

To perform a plasma cleaning process, an integrated circuit is placed in a plasma chamber and a pump removes the process gases from the process chamber. Electromagnetic energy (e.g., radio frequency) is applied to an injected gas, such as argon, to excite the injected gas into a plasma state. The plasma generates ions from the injected gas that bombard the surface of the substrate to remove contaminants and/or material from the substrate surface. Atoms or molecules of the contaminants and/or substrate material are, for the most part, pumped out of the chamber.

Therefore, there is a need for an improved plasma processing chamber that can efficiently remove contaminants and/or material from a surface of a substrate.

### SUMMARY

Certain aspects provided herein generally include apparatus, plasma processing systems and methods for removing contaminants and/or material from a surface of a substrate during substrate processing and/or while performing a chamber cleaning process.

One example apparatus generally includes: a plasma impeding element disposed adjacent to a substrate support element of a chamber, wherein the plasma impeding element includes a surface with one or more openings configured to allow fluid flow from an upper region of the chamber to a lower region of the chamber; and one or more straps coupled configured to be coupled between the plasma impeding element and a grounded body, wherein the one or more straps are disposed within the lower region of the chamber.

One example method generally includes: processing a substrate disposed on a substrate support element of a chamber, wherein the processing results in impurities within an upper region of the chamber; removing, via a pump, the impurities from the upper region of the chamber to a lower region of the chamber through one or more opening of a surface of a plasma impeding element disposed adjacent to the substrate support element; and grounding the plasma impeding element via one or more straps coupled between the plasma impeding element and a grounded body, wherein the one or more straps are disposed within the lower region of the chamber.

One example plasma chamber generally includes: a substrate support element configured to support a substrate to be processed in the chamber, wherein the processing the substrate results in impurities within an upper region of the chamber; a pump configured to remove the impurities from an upper region of the chamber to a lower region of the chamber; a plasma impeding element disposed adjacent to the substrate support element, wherein the plasma impeding element includes a surface with one or more openings configured to allow fluid flow from the upper region of the chamber to the lower region of the chamber to facilitate the removal of the impurities; and one or more straps coupled configured to be coupled between the plasma impeding element and a grounded body, wherein the one or more straps are disposed within the lower region of the chamber.

### BRIEF DESCRIPTION OF THE DRAWINGS

So that the manner in which the above recited features of the present disclosure can be understood in detail, a more particular description of the disclosure, briefly summarized above, may be had by reference to aspects, some of which are illustrated in the appended drawings. It is to be noted, however, that the appended drawings illustrate only exemplary aspects and are therefore not to be considered limiting of its scope, and may admit to other equally effective aspects.

FIG. 1 depicts a schematic side view of a process chamber in accordance with at least some aspects of the present disclosure.

FIG. 2 depicts a partial schematic cross-sectional side view of a process chamber in accordance with at least some aspects of the present disclosure.

FIG. 3 depicts a partial schematic cross-sectional side view of a process chamber with a radio frequency (RF) choke, in accordance with certain aspects of the present disclosure.

FIG. 4 depicts a partial schematic cross-sectional side view of a process chamber with a flat RF choke, in accordance with certain aspects of the present disclosure.

FIG. 5 depicts a partial schematic cross-sectional side view of a process chamber with a tapered RF choke, in accordance with certain aspects of the present disclosure.

FIG. 6 is a flow diagram illustrating example operations for chamber cleaning, in accordance with certain aspects of the present disclosure.

To facilitate understanding, identical reference numerals have been used, where possible, to designate identical elements that are common to the figures. It is contemplated that elements and features of one aspect may be beneficially incorporated in other aspects without further recitation.

### DETAILED DESCRIPTION

Certain aspects of the present disclosure are directed towards a radio frequency (RF) choke for use in a process chamber. The process chamber may be configured to perform any suitable plasma process to a substrate. In some aspects, the process chamber is configured to perform an etch process, a deposition process, or a preclean process. The process chamber includes a substrate support to support the substrate. A pump may be coupled to the process chamber to remove gases, contaminants, and particles from an interior volume of the process chamber. In some cases, a RF choke may be disposed about the substrate to block RF plasma from leaking from a processing volume of the chamber to a lower region of the chamber while also allowing gas conductance for impurities to be removed from the processing volume.

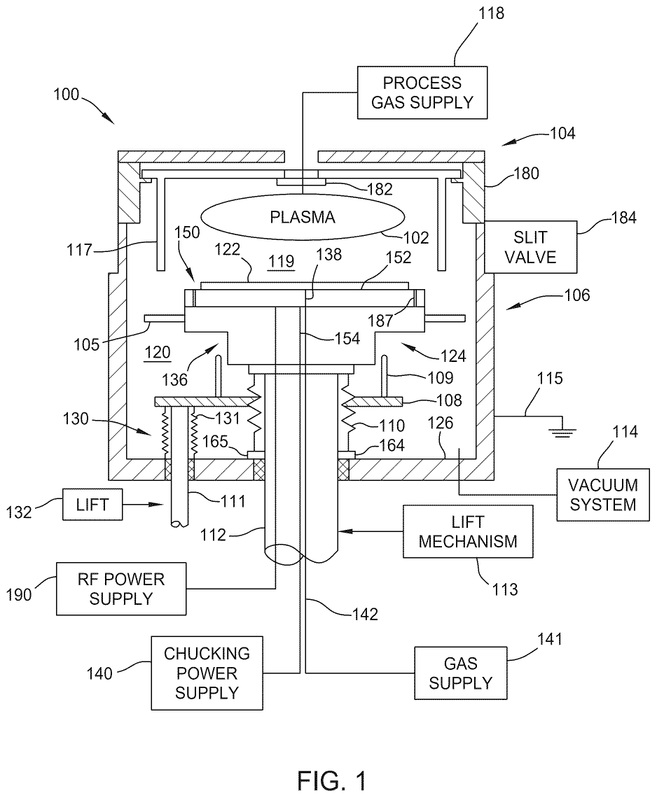

FIG. 1 depicts a schematic side view of a process chamber (e.g., a plasma processing chamber) having a process kit in accordance with at least some aspects of the present disclosure. In some aspects, the plasma processing chamber is a preclean processing chamber. However, other types of process chambers configured for different processes can also use or be modified for use with aspects of the process kit described herein.

The chamber 100 is a vacuum chamber which is suitably adapted to maintain sub-atmospheric pressures within an interior volume 120 during substrate processing. In some aspects, the chamber 100 can maintain a pressure of about 1 mTorr to about 10 mTorr. The chamber 100 includes a chamber body 106 covered by a lid 104 which encloses a processing volume 119 located in the upper half of the interior volume 120. In some aspects, the chamber 100 includes an adapter 180 disposed between the chamber body 106 and the lid 104 and resting on sidewalls of the chamber body 106. The chamber 100 includes a process kit circumscribing various chamber components to prevent unwanted reaction between such components and etched material and other contaminants. The chamber body 106, the adapter 180, and the lid 104 may be made of metal, such as aluminum. The chamber body 106 may be grounded via a coupling to ground 115.

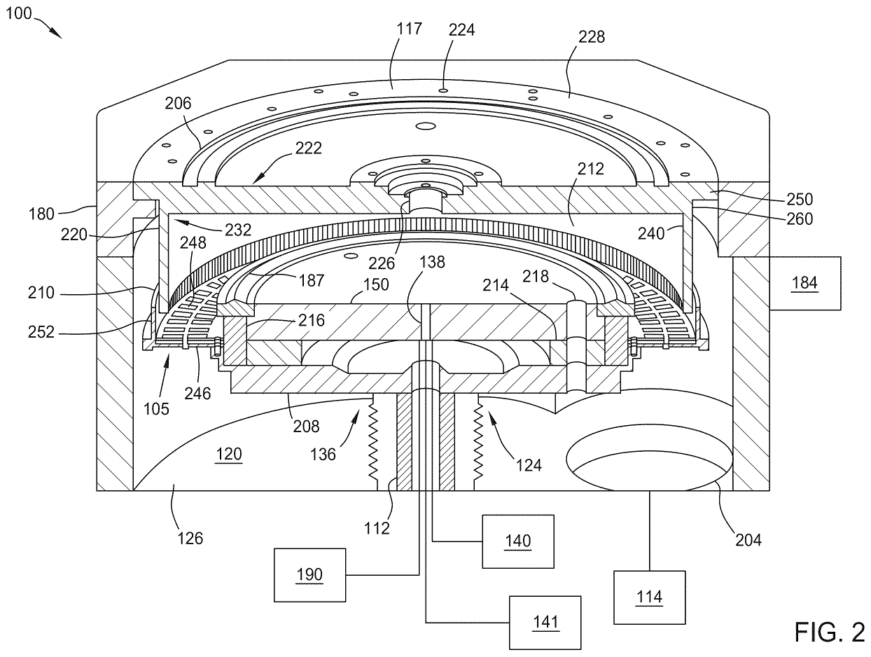

A substrate support 124 is disposed within the interior volume 120 to support and retain a substrate 122, such as a semiconductor substrate, for example, or other such substrate as may be electrostatically retained. The substrate support 124 may generally comprise a pedestal 136 (described in more detail below with respect to FIG. 2) and a hollow support shaft 112 for supporting the pedestal 136. The pedestal 136 includes an electrostatic chuck 150. In some aspects, the electrostatic chuck 150 comprises a dielectric plate. The hollow support shaft 112 provides a conduit to provide, for example, backside gases, process gases, fluids, coolants, power, or the like, to the electrostatic chuck 150. In some aspects, the substrate support 124 includes an edge ring 187 disposed about the electrostatic chuck 150. In some aspects, the edge ring 187 is made of alumina (Al₂O₃). A slit valve 184 may be coupled to the chamber body 106 to facilitate transferring the substrate 122 into and out of the interior volume 120.

In some aspects, the process kit includes an inner shield 117 (e.g. also referred to herein as an upper shield) circumscribing the substrate support 124. In some aspects, the inner shield 117 rests on the adapter 180. In some aspects, the inner shield 117 is configured to define the processing volume 119. In some aspects, the inner shield 117 is made of metal such as aluminum. In some aspects, the process kit includes a lower shield 105 circumscribing the substrate support 124. In some aspects, the lower shield 105 is coupled to the pedestal 136. In some aspects, the lower shield 105 is made of metal such as aluminum.

In some aspects, the hollow support shaft 112 is coupled to a lift mechanism 113, such as an actuator or motor, which provides vertical movement of the electrostatic chuck 150 between an upper, processing position, and a lower, transfer position. A bellows assembly 110 is disposed about the hollow support shaft 112 and is coupled between the electrostatic chuck 150 and a bottom surface 126 of chamber 100 to provide a flexible seal that allows vertical motion of the electrostatic chuck 150 while reducing or preventing loss of vacuum from within the chamber 100. The bellows assembly 110 also includes a lower bellows flange 164 in contact with an o-ring 165 or other suitable sealing element which contacts the bottom surface 126 to help prevent loss of chamber vacuum.

A substrate lift 130 can include lift pins 109 mounted on a platform 108 connected to a shaft 111 which is coupled to a second lift mechanism 132 for raising and lowering the substrate lift 130 so that the substrate 122 may be placed on or removed from the electrostatic chuck 150. The electrostatic chuck 150 may include thru-holes to receive the lift pins 109. A bellows assembly 131 is coupled between the substrate lift 130 and bottom surface 126 to provide a flexible seal which maintains the chamber vacuum during vertical motion of the substrate lift 130.

The hollow support shaft 112 provides a conduit for coupling a backside gas supply 141, a chucking power supply 140, and a RF power supply 190 to the electrostatic chuck 150. In some aspects, the chucking power supply 140 provides DC power to the electrostatic chuck 150 via conduit 154 to retain the substrate 122. In some aspects, RF energy supplied by the RF power supply 190 may have a frequency of about 10 MHz or greater. In some aspects, the RF power supply 190 may have a frequency of about 13.56 MHz.

In some aspects, the backside gas supply 141 is disposed outside of the chamber body 106 and supplies gas to the electrostatic chuck 150. In some aspects, the electrostatic chuck 150 includes a gas channel 138 extending from a lower surface of the electrostatic chuck 150 to an upper surface 152 of the electrostatic chuck 150. The gas channel 138 is configured to provide backside gas, such as nitrogen (N), argon (Ar), or helium (He), to the upper surface 152 of the electrostatic chuck 150 to act as a heat transfer medium. The gas channel 138 is in fluid communication with the backside gas supply 141 via gas conduit 142 to control the temperature and/or temperature profile of the substrate 122 during use. For example, the backside gas supply 141 can supply gas to cool the substrate 122 during use.

The chamber 100 is coupled to and in fluid communication with a vacuum system 114 which includes a throttle valve (not shown) and pump (not shown) which are used to exhaust the chamber 100. In some aspects, the vacuum system 114 is coupled to a pump port disposed on the bottom surface 126 of the chamber body 106. The pressure inside the chamber 100 may be regulated by adjusting the throttle valve and/or vacuum pump (e.g., mechanical pump and/or turbomolecular vacuum pump, etc.). In some aspects, the pump has a flow rate of about 1900 liters per second to about 3000 liters per second.

The chamber 100 is also coupled to and in fluid communication with a process gas supply 118 which may supply one or more process gases to the chamber 100 for processing a substrate disposed therein. In some aspects, the lid 104 includes a port through which gas from the process gas supply 118 can be introduced into the interior volume 120. In some aspects, the process gas supply 118 provides argon (Ar), helium (He), hydrogen (H₂), or other suitable process gas. In some aspects, a diffuser 182 is coupled to the inner shield 117 to inject gas from the process gas supply 118 into the processing volume 119. In some aspects, the diffuser 182 is configured to inject gas into the processing volume 119 from a center of the inner shield 117.

In operation, for example, a plasma 102 may be created in the interior volume 120 to perform one or more processes. The plasma 102 may be created by coupling power from a plasma power source (e.g., RF power supply 190) to a process gas via the substrate support 124 to ignite the process gas and create the plasma 102. The RF power supply 190 is also configured to attract ions from the plasma towards the substrate 122.

FIG. 2 depicts a partial schematic cross-sectional side view of a process chamber in accordance with at least some aspects of the present disclosure. In some aspects, the pedestal 136 of the substrate support 124 includes a bottom housing 208 formed of metal and coupled to the hollow support shaft 112. The bottom housing 208 is coupled to ground (e.g., ground 115). In some aspects, the pedestal 136 includes the electrostatic chuck 150 disposed on the bottom housing 208 with an isolator 214 disposed therebetween. The isolator 214 is configured to electrically isolate the electrostatic chuck 150 and the bottom housing 208. In some aspects, the isolator 214 is ring shaped. In some aspects, one or more lift pins holes 218 extend through the bottom housing 208, the isolator 214, and the electrostatic chuck 150 to allow one or more lift pins (e.g., lift pins 109) to pass through. In some aspects, a second isolator 216 is disposed about the isolator 214 and between the bottom housing 208 and the edge ring 187 to electrically isolate the edge ring 187 from the bottom housing 208.

In some aspects, the inner shield 117 is mounted on the adapter 180 and surrounds the electrostatic chuck 150. In some aspects, the inner shield 117 is disposed proximate the lid 104 to define an upper portion of the processing volume 119. The inner shield 117 is configured to confine the plasma 102 during use. In some aspects, the inner shield 117 is coupled to the lid 104.

The inner shield 117 includes a tubular body 220 having an inner surface 212. The inner surface 212 defines a central opening 240 configured to surround the substrate support 124. In some aspects, sidewalls of the tubular body 220 do not include any through holes. An upper end of the tubular body 220 is coupled to a top plate 222 at an interface 232. The top plate 222 substantially covers the central opening 240 at one end of the tubular body 220. In some aspects, the top plate 222 is circular in shape. In some aspects, the top plate 222 has a diameter that is greater than an outer diameter of the tubular body 220. In some aspects, the tubular body 220 extends straight down from the top plate 222. In some aspects, the central opening 240 of the tubular body 220 has a diameter of about 15.0 inches to about 19.0 inches.

In some aspects, the top plate 222 has an upper portion 250 and a lower portion 260. In some aspects, the upper portion 250 extends radially outward of the lower portion 260. In some aspects, an outer diameter of the lower portion 260 is substantially the same as the outer diameter of the tubular body 220. The top plate 222 includes a gas inlet 226 configured to provide a process gas therethrough (e.g., from process gas supply 118). In some aspects, the gas inlet 226 has a diameter less than an outer diameter of the substrate support 124.

In some aspects, an upper surface 228 of the top plate 222 includes a first annular recess 206 configured to accommodate an o-ring to provide a vacuum seal between the inner shield 117 and the lid 104.

In some aspects, the lower shield 105 is coupled to the bottom housing 208 to support and ground the lower shield 105. The lower shield 105 comprises an annular ring 246 configured to surround the substrate support and an annular lip 252 extending from an upper surface 248 of the annular ring 246.

In some aspects, the outer diameter of the tubular body 220 is less than an inner diameter of the annular lip 252 such that the annular lip 252 is disposed about the tubular body 220. In some aspects, one or more metal straps are disposed between the inner shield 117 and the lower shield 105 to advantageously ground the inner shield 117. In some aspects, the one or more metal straps are coupled to the annular lip 252. In some aspects, the metal straps are configured to contact the tubular body 220 when the chamber 100 is in the process position and configured to be spaced from the tubular body 220 when the chamber 100 is in the transfer position.

A pump port 204 is coupled to a pump (e.g., pump of vacuum system 114) and facilitates removal of particles from the interior volume 120 through a gap between the tubular body 220 and the substrate support 124. For example, the particles may be impurities that may be removed through the shield 105. The shield 105 may block leakage of RF plasma from a substrate processing volume of the chamber above the shield 105 to below the shield 105. Thus, the shield 105 may also be referred to herein as an RF choke.

### RF Choke for Particle Reduction and Increased Conductance

A pre-clean or etch chamber uses radio frequency (RF) plasma to etch the metal oxide from a substrate. However, as the RF plasma is not selective, both metal and dielectric on the substrate are etched, causing impurities to be generated in the chamber. For instance, during substrate processing, particles (impurities) may be deposited on an upper shield (e.g., tubular body 220 of shield 117). The generated impurities can also be pumped out using a pump through an RF choke (e.g., corresponding to the shield 105 described with respect to FIGS. 1 and 2). Thus, it is important for the RF choke to have high gas conductance (e.g., low resistance to gas flow) to facilitate efficient removal of the etched material (e.g., impurities) in the chamber but also prevent plasma leakage into the lower portion of the chamber. The RF choke may be grounded to prevent arcing and secondary plasma. For example, the RF choke may block leakage of RF plasma from the processing volume of the chamber above the RF choke to the lower region of the chamber.

Typical RF chokes may have low gas conductance, resulting in reduced pumping efficiency causing inefficient removal of the generated impurities from the process volume. Moreover, ground straps for typical RF choke implementations may be disposed within the substrate processing volume, and provide a path to ground. As a result, the generated impurities, such as a plasma processing by-product such as a polymer by-product, a metal containing material, and/or a silicon containing material (e.g., silicon nitride (SiN)) created while processing a typical semiconductor substrate, may deposit on the ground straps. Due to the deposition on the ground straps, the deposited impurities on the ground straps may begin flaking and depositing particles on the substrate.

Certain aspects of the present disclosure are directed towards an RF choke with a flat or tapered design that provides increased surface area and slots (e.g., openings) for gas flow, increasing gas conductance. Moreover, the RF choke may be implemented with ground straps disposed below the RF choke such that the ground straps are not in the process volume of the chamber. In other words, the ground straps, which provide a path to ground between the RF choke and grounded surface of the chamber body 106, may be disposed in a region of the chamber that is blocked from being exposed to the generated RF plasma, preventing the flaking of the straps and deposition of particles on the substrate.

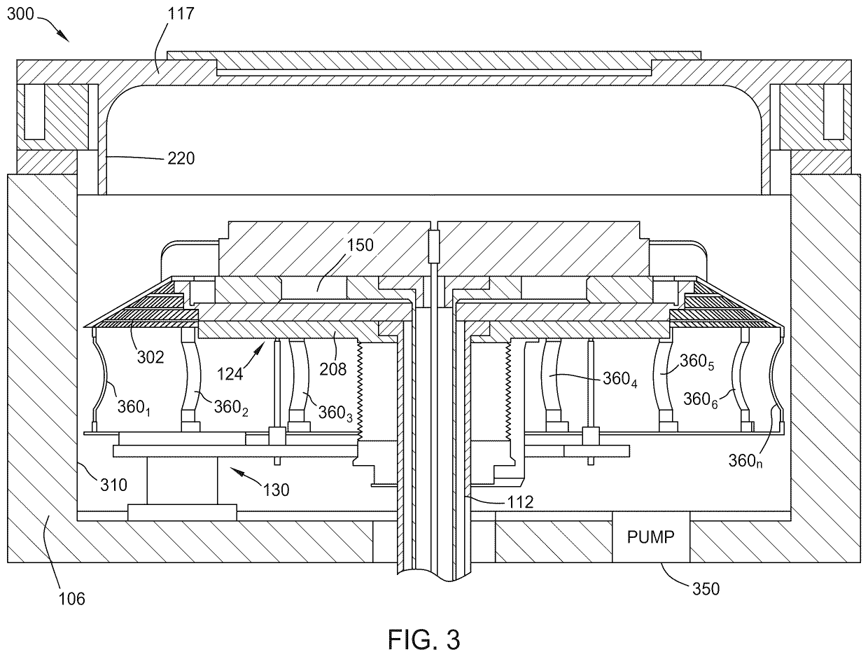

FIG. 3 depicts a partial schematic cross-sectional side view of a process chamber 300, in accordance with certain aspects of the present disclosure. As shown, the chamber may include an RF choke 302 (e.g., shield). The RF choke 302 may have a flat surface (e.g., entirely flat surface) with slots to facilitate the flow of gas from a region above the choke 302 to a region below the choke 302 during processing in which a gas is removed from the interior of the chamber body 106 via a pump 350 (e.g., corresponding to the pump port 204 coupled to a pump such as the pump of vacuum system 114). The RF choke 302 is configured to provide a lower pressure drop with respect to a gas flow through a conventional lower shield design that has a lower conductance. In other words, during the pumping of the gas to remove impurities, the pressure within the processing volume above the choke 302 may be reduced as compared to chambers using conventional RF lower shields. The lower pressure indicates less resistance to the flow of gas from the process volume to below the RF choke. The RF choke 302 may provide improved particle performance (e.g., particle migration during pumping) as compared to existing RF chokes due to the higher gas conductance.

In some aspects, the series of ground straps 360₁ to 360ₙ (n being a positive integer) may be coupled between the RF choke 302 and a sidewall 310 of the chamber body 106. Ground straps 360₁ to 360ₙ may be collectively referred to herein as ground straps 360. The chamber body 106 may be grounded. Thus, the ground straps 360 may be used to ground the RF choke. As shown, the ground straps 360 are disposed below the RF choke outside the processing volume that is above RF choke 302. In some aspects, the straps 360 may be flexible to allow the lift 130 to raise or lower the substrate 124 with the RF choke 302.

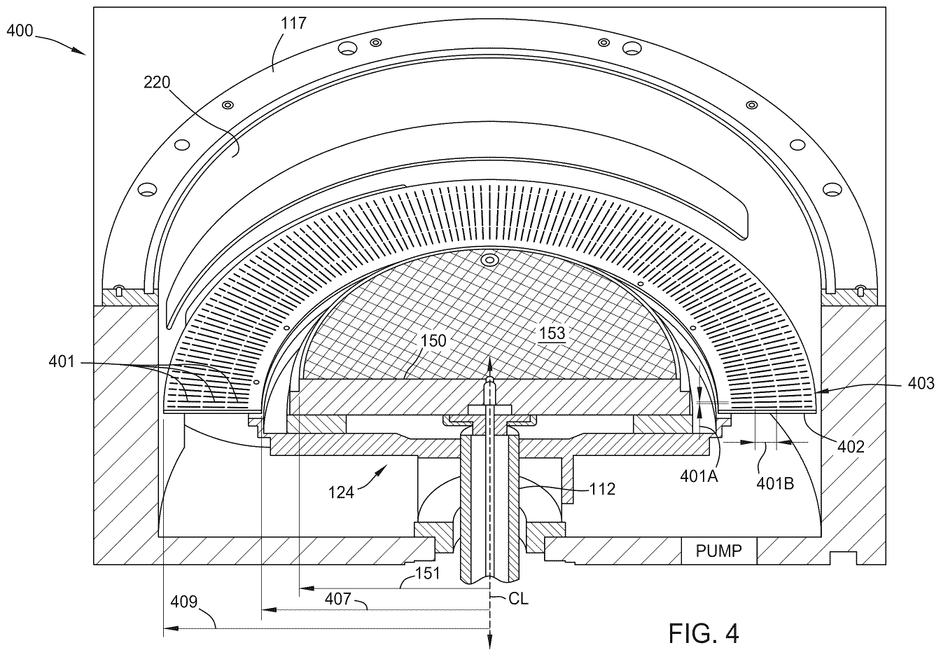

FIG. 4 depicts a partial schematic cross-sectional side view of a process chamber 400 with a flat RF choke 402, in accordance with certain aspects of the present disclosure. As shown, the RF choke 402 may have be an annular ring with multiple rows of slots 401 (gaps) for gas flow. In some aspects, there may be at least three rows of slots 401 to increase the gas conductance of the choke 402. As shown, the RF choke 402 may have a flat surface from an inner circumference of the ring to an outer circumference of the ring. The RF choke 402 may have increased surface area with slots 401 (gaps) to increase the choke's gas conductance, as compared to typical RF choke implementations. In some embodiments, the slots 401 are aligned in a radial orientation. As shown in FIG. 4, in one non-limiting example, the slots 401 include a width 401A measured perpendicular to the radial direction and a length 401B measured in the radial direction. In some embodiments, the width 401A is between 2.0 millimeters (mm) and 3.0 mm, and the length 401B is between 6.0 mm and 17.0 mm. An upper surface 403 of the RF choke 402 may also include a RF choke surface area, which defined between an inner radius 407 (R₄₀₇) and an outer radius 409 (R₄₀₉), wherein the inner radius 407 and an outer radius 409 are both larger than the radius 151 of a substrate supporting surface 153. In some embodiments, a ratio of the surface area of the RF choke surface to the surface area of the substrate supporting surface 153 is between 1.3 and 1.5.

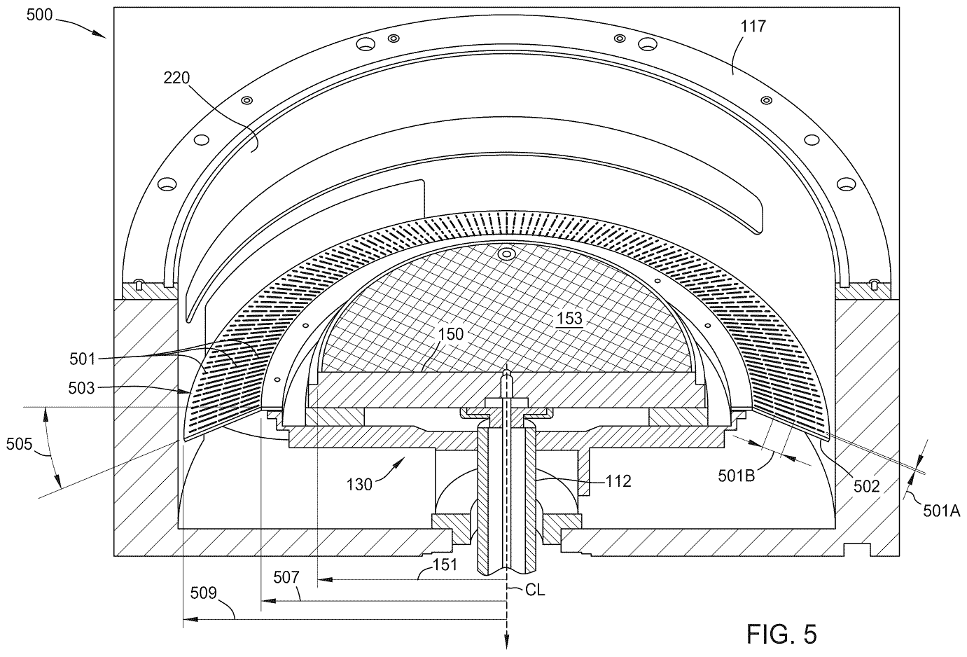

FIG. 5 depicts a partial schematic cross-sectional side view of a process chamber 500 with a tapered RF choke 502, in accordance with certain aspects of the present disclosure. As shown, the RF choke 502 may be tapered in some cases. In some embodiments, the upper surface 503 of the RF choke 502 has taper angle 505 of between 0 and 60 degrees. The upper surface 503 of the RF choke 502 may also include a RF choke surface area, which defined between an inner radius 507 (R₅₀₇) and an outer radius 509 (R₅₀₉), wherein the inner radius 507 and an outer radius 509 are both larger than the radius 151 of a substrate supporting surface 153. In some embodiments, a ratio of the surface area of the RF choke surface to the surface area of the substrate supporting surface 153 is between 1.3 and 1.5. By tapering the RF choke, the surface area of the choke may be further increased versus the configuration illustrated in FIG. 4 to increase the gas conductance. In some embodiments, the slots 501 are aligned in a radial orientation. As shown in FIG. 5, in one non-limiting example, the slots 501 include a width 501A measured perpendicular to the radial direction and a length 501B measured in the radial direction. In some embodiments, the width 501A is between 2.0 mm and 3.0 mm, and the length 501B is between 6.0 mm and 17.0 mm.

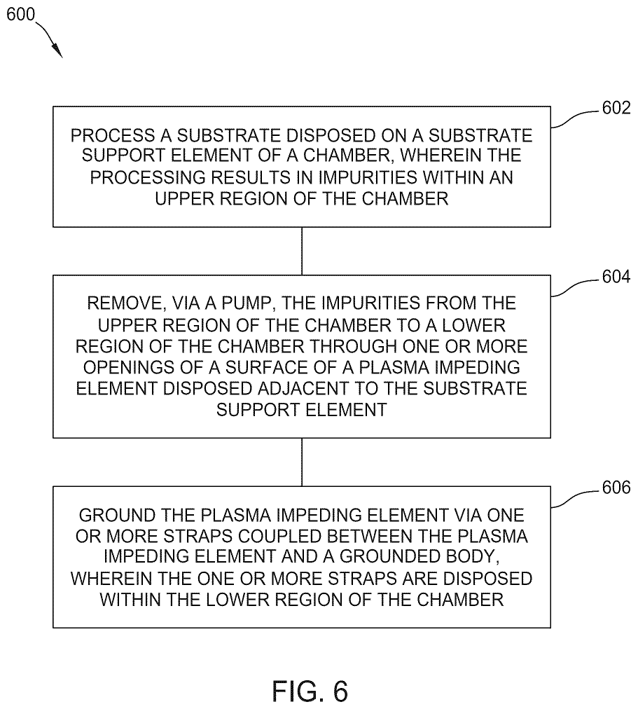

FIG. 6 is a flow diagram illustrating example operations 600 for plasma processing, in accordance with certain aspects of the present disclosure. The operations 600 may be performed by a process chamber, such as the chamber 100.

At block 602, the chamber may process a substrate disposed on a substrate support surface 153 of a substrate support 124 within the process chamber. The processing may result in impurities within an upper region (e.g., processing volume 119) of the chamber.

At block 604, the chamber may remove, via a pump (e.g., pump of vacuum system 114), the impurities from the upper region (e.g., processing volume 119) of the chamber to a lower region (e.g., interior volume 120) of the chamber through one or more opening of a surface of a plasma impeding element (e.g., RF choke 302, 402, or 502) disposed adjacent to the substrate support element.

At block 606, the chamber may ground the plasma impeding element via one or more straps (e.g., straps 360) coupled between the plasma impeding element and a grounded body. The one or more straps may be disposed within the lower region of the chamber. In some aspects, a first edge of each the one or more straps may be coupled to the plasma impeding element, and a second edge of each of the one or more straps may be coupled the grounded body. In one configuration, the one or more straps may be coupled to an outer edge of the plasma impeding element, such as an edge at an outer radius (e.g., outer radius 409, 509) of the plasma impeding element. The grounded body may include a sidewall (e.g., sidewall 310) of a housing (e.g., body 106) of the chamber. Each of the one or more straps may be flexible to allow vertical movement of the plasma impeding element. Each of the one or more straps may include a flexible metal material such as a thin metal element that comprises copper, beryllium copper, stainless steel, or other useful material.

In some aspects, the chamber block, via the plasma impeding element, leakage of RF plasma from the upper region to the lower region during the processing of the substrate. The plasma impeding element may include an annular ring. A surface of the annular ring from an inner circumference of the annular ring to an outer surface of the annular ring may be flat. In some cases, the annular ring may be tapered. In some aspects, the annular ring may include at least three rows of openings configured to allow the fluid to flow therethrough.

While the foregoing is directed to aspects of the present disclosure, other and further aspects of the disclosure may be devised without departing from the basic scope thereof, and the scope thereof is determined by the claims that follow.

What is claimed is:

1. A plasma processing apparatus, comprising:
a plasma impeding element disposed adjacent to a substrate support element of a chamber, wherein the plasma impeding element includes a surface with a plurality of openings configured to allow fluid to flow from an upper region of the chamber to a lower region of the chamber; and
one or more straps coupled configured to be coupled between the plasma impeding element and a grounded body, wherein the one or more straps are disposed within the lower region of the chamber.

2. The plasma processing apparatus of claim 1, wherein a first edge of each the one or more straps is configured to be coupled to the plasma impeding element, and wherein a second edge of each of the one or more straps is configured to be coupled the grounded body.

3. The plasma processing apparatus of claim 1, wherein the grounded body comprises a sidewall of a housing of the chamber.

4. The plasma processing apparatus of claim 1, wherein the plasma impeding element comprises a radio frequency (RF) choke configured to block leakage of RF plasma from the upper region to the lower region during processing of a substrate.

5. The plasma processing apparatus of claim 1, wherein the plasma impeding element comprises an annular ring.

6. The plasma processing apparatus of claim 5, wherein a surface of the annular ring from an inner circumference of the annular ring to an outer surface of the annular ring is flat.

7. The plasma processing apparatus of claim 5, wherein the annular ring is tapered.

8. The plasma processing apparatus of claim 5, wherein the annular ring comprises at least three rows of openings configured to allow the fluid flow.

9. The plasma processing apparatus of claim 1, wherein each of the one or more straps is flexible to allow vertical movement of the plasma impeding element.

10. The plasma processing apparatus of claim 1, further comprising a pump configured to remove impurities from the upper region through the one or more openings of the plasma impeding element.

11. A method for processing a substrate, comprising:
generating a plasma over a substrate disposed on a substrate support element of a chamber, wherein the generated plasma generates impurities within an upper region of the chamber;
removing, via a pump, the impurities from the upper region of the chamber to a lower region of the chamber through a plurality of opening formed through a surface of a plasma impeding element disposed adjacent to the substrate support element; and
grounding the plasma impeding element via one or more straps coupled between the plasma impeding element and a grounded body, wherein the one or more straps are disposed within the lower region of the chamber.

12. The method of claim 11, wherein a first edge of each the one or more straps is configured to be coupled to the plasma impeding element, and wherein a second edge of each of the one or more straps is configured to be coupled the grounded body.

13. The method of claim 11, wherein the grounded body comprises a sidewall of a housing of the chamber.

14. The method of claim 11, further comprising blocking, via the plasma impeding element, leakage of RF plasma from the upper region to the lower region during the processing of the substrate.

15. The method of claim 11, wherein the plasma impeding element comprises an annular ring.

16. The method of claim 15, wherein a surface of the annular ring from an inner circumference of the annular ring to an outer surface of the annular ring is flat.

17. The method of claim 15, wherein the annular ring is tapered.

18. The method of claim 15, wherein the annular ring comprises at least three rows of openings configured to allow the removing of the impurities.

19. The method of claim 11, wherein each of the one or more straps is flexible to allow vertical movement of the plasma impeding element.

20. A plasma chamber, comprising:
a substrate support element configured to support a substrate to be processed in the chamber, wherein the processing the substrate results in impurities within an upper region of the chamber;
a pump configured to remove the impurities from an upper region of the chamber to a lower region of the chamber;
a plasma impeding element disposed adjacent to the substrate support element, wherein the plasma impeding element includes a surface with a plurality of openings configured to allow fluid flow from the upper region of the chamber to the lower region of the chamber to facilitate the removal of the impurities; and
one or more straps coupled configured to be coupled between the plasma impeding element and a grounded body, wherein the one or more straps are disposed within the lower region of the chamber.
